(19) United States
(12) Patent Application Publication
(10) Pub. No.: US 2026/0018556 A1
(43) Pub. Date: Jan. 15, 2026

(54) SUBSTRATE BONDING DEVICE, SUBSTRATE BONDING SYSTEM INCLUDING THE SAME, AND SUBSTRATE BONDING METHOD USING THE SAME

(71) Applicant: SAMSUNG ELECTRONICS CO., LTD., Suwon-si (KR)

(72) Inventors: Sangjun PARK, Suwon-si (KR); Taehong MIN, Suwon-si (KR); Junhwa PARK, Suwon-si (KR); Sang-Ho YUN, Suwon-Si (KR); Jaeho HONG, Suwon-si (KR)

(73) Assignee: SAMSUNG ELECTRONICS CO., LTD., Suwon-si (KR)

(21) Appl. No.: 19/054,363

(22) Filed: Feb. 14, 2025

(30) Foreign Application Priority Data
Jul. 15, 2024 (KR) 10-2024-0093188

(51) Int. Cl. H01L 23/00; H01L 21/67; H01L 21/677

(52) U.S. Cl. CPC H01L 24/74; H01L 21/67121; H01L 24/80; H01L 21/67748; H01L 2224/8013; H01L 2224/80201; H01L 2224/80894; H01L 2224/80948

(57) ABSTRACT

A substrate bonding device including: a bonding chamber including (i) a loading region in which a lower substrate is loaded, (ii) a bonding region in which an upper substrate is bonded to the lower substrate, and (iii) an unloading region spaced from the loading region and unloading the lower substrate to which the upper substrate is bonded in an internal space; a plurality lower chucks configured to support the lower substrate, each lower chuck moveable to be sequentially disposed in the loading region, the bonding region, and the unloading region; and an upper chuck configured to support the upper substrate to face the lower substrate in the bonding region.

### CROSS-REFERENCE TO RELATED APPLICATION

This application claims priority to and the benefit of Korean Patent Application No. 10-2024-0093188 filed in the Korean Intellectual Property Office on Jul. 15, 2024, the entire contents of which are incorporated herein by reference.

### BACKGROUND

### 1. Field

The present disclosure relates to a substrate bonding device, a substrate bonding system including the same, and a substrate bonding method using the substrate bonding device.

### 2. Description of the Related Art

During a process for manufacturing a semiconductor device, a process for mutually bonding at least two substrates may be performed. The substrate bonding process may be performed by a wafer method for directly bonding two wafers without using a medium.

In the substrate bonding process, an upper substrate and a lower substrate are bonded while supported by a pair of chucks. The bonded substrates may be transferred to an annealing device through a transfer system such as an overhead hoist transport (OHT), and may undergo an annealing process.

However, the conventional substrate bonding process using a pair of chucks has low productivity. Further, the upper substrate and the lower substrate may be tilted and de-bonded from each other when transferring the bonded substrate.

### SUMMARY

The present disclosure is directed to a substrate bonding device and a substrate bonding method for increasing productivity.

The present disclosure is directed to a substrate bonding system for preventing the upper substrate and the lower substrate on the bonding substrate from being tilted and de-bonded from each other.

According to an aspect of the disclosure, a substrate bonding device including: a bonding chamber including (i) a loading region in which a lower substrate is loaded, (ii) a bonding region in which an upper substrate is bonded to the lower substrate, and (iii) an unloading region spaced from the loading region and unloading the lower substrate to which the upper substrate is bonded in an internal space; a plurality lower chucks configured to support the lower substrate, each lower chuck moveable to be sequentially disposed in the loading region, the bonding region, and the unloading region; and an upper chuck configured to support the upper substrate to face the lower substrate in the bonding region.

According to an aspect of the disclosure, a substrate bonding system including: a substrate bonding device comprising (i) a plurality of lower chucks configured to support a lower substrate, each lower chuck moveable in a first direction and a second direction that is perpendicular to the first direction, and (ii) an upper chuck configured to support an upper substrate that faces the lower substrate on the plurality of lower chucks; a first transfer module configured to load the lower substrate on the substrate bonding device; a heat processing device arranged near the substrate bonding device, and the heat processing device configured to heat-treat the lower substrate bonded with the upper substrate unloaded from the substrate bonding device; and a second transfer module configured to unload a lower substrate bonded with the upper substrate from the substrate bonding device and load the lower substrate bonded with the upper substrate on the heat processing device.

According to an aspect of the disclosure, a method for bonding an upper substrate on a lower substrate by using a substrate bonding device including an upper chuck for supporting the upper substrate, and a first lower chuck and a second lower chuck supporting the lower substrate, the method includes: arranging the first lower chuck in a loading region to load the lower substrate on the first lower chuck; moving the first lower chuck from the loading region to a bonding region; bonding, in the bonding region, the upper substrate supported on the upper chuck to the lower substrate supported on the first lower chuck; and moving the first lower chuck from the bonding region to an unloading region to unload the lower substrate bonded with the upper substrate, wherein between the moving of the first lower chuck to the bonding region and the bonding, the second lower chuck is arranged in the loading region to load another lower substrate on the second lower chuck.

According to the embodiments, productivity of the substrate bonding process may be increased by using the substrate bonding device including lower chucks.

The productivity may be increased and the debonding issue generated when moving the bonding substrate may be solved by continuously performing the substrate bonding process and the heat treatment process.

### BRIEF DESCRIPTION OF DRAWINGS

FIG. 1 shows a top plan view of a substrate bonding system according to one or more embodiments.

FIG. 2 shows a substrate bonding process using a substrate bonding system according to one or more embodiments.

FIG. 3 shows a cross-sectional view of a substrate bonding device according to one or more embodiments.

FIG. 4 shows a top plan view of a substrate bonding device according to one or more embodiments.

FIG. 5 shows an upper chuck and a lower chuck of a substrate bonding device according to one or more embodiments.

FIG. 6 and FIG. 7 show a process for bonding an upper substrate and a lower substrate by using a substrate bonding device according to one or more embodiments.

FIG. 8 to FIG. 10 show top plan views of part of a substrate bonding device according to various embodiments.

FIG. 11 to FIG. 15 show a method for bonding an upper substrate and a lower substrate using a substrate bonding device according to one or more embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification.

The size and thickness of each configuration shown in the drawings are arbitrarily shown for better understanding and ease of description, but the present disclosure is not limited thereto.

Throughout this specification and the claims that follow, when it is described that an element is “coupled” to another element, the element may be “directly coupled” to the other element or “indirectly coupled” to the other element through a third element. Unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. It will be understood that when an element such as a layer, film, region, or substrate is referred to as being “on” another element, it may be directly on the other element or intervening elements may also be present.

The phrase “in a plan view” means viewing an object portion from the top, and the phrase “in a cross-sectional view” means viewing a cross-section of which the object portion is perpendicularly cut from the side.

A substrate bonding device, a substrate bonding method, and a substrate bonding system according to various embodiments will now be described with reference to accompanying drawings.

In the present specification, the substrate used in a substrate bonding system, a substrate bonding device, a upper substrate, and a lower substrate may be a wafer for manufacturing a semiconductor device, and the wafer will now be described as an example of the substrate. However, the substrate is not limited to the wafer, and include anything called as substrates as a wide-range meaning.

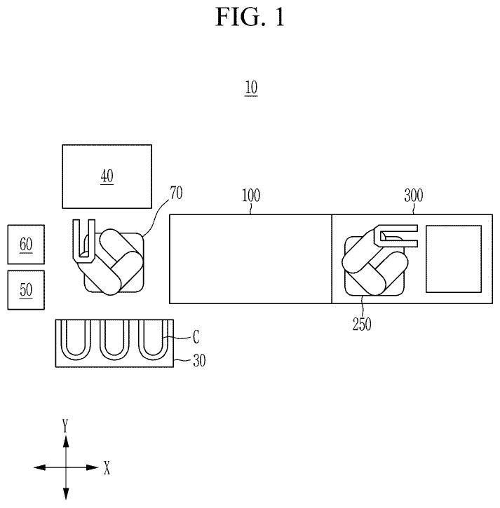

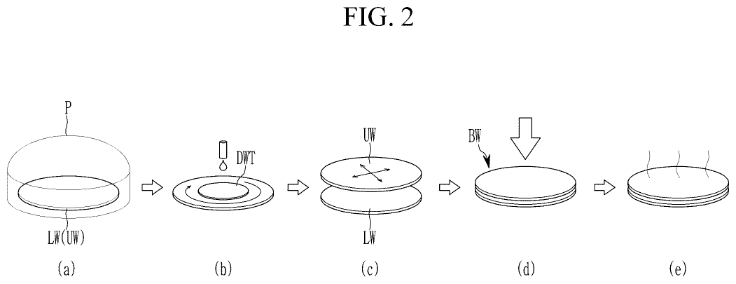

FIG. 1 shows a top plan view of a substrate bonding system according to one or more embodiments, and FIG. 2 shows a substrate bonding process using a substrate bonding system according to one or more embodiments.

Referring to FIG. 1, the substrate bonding system 10 includes a substrate bonding device 100, a first transfer module 70, a second transfer module 250, and a heat processing device 300. The substrate bonding system 10 may further include a plasma processing device 40 corresponding to a preprocessing device, and a cleaning device 50. The substrate bonding system 10 may further include an aligning device 60 and a receiving module 30. In one or more examples, the substrate bonding system 10 may be arranged in a clean room. Hence, the substrate bonding process using the substrate bonding system 10 may be performed in a space in which dusts and foreign substances are blocked.

The plasma processing device 40 may perform a plasma treatment on surfaces of substrates LW and UW (FIG. 2). For example, the plasma processing device 40 may irradiate plasma (P) on bonded surfaces of the substrates LW and UW to activate the bonded surfaces (refer to (a) of FIG. 2). The plasma (P) generated by the plasma processing device 40 may be one of inductive coupled plasma, capacitive coupled plasma, and microwave-type plasma. However, as understood by one of ordinary skill in the art, the embodiments are not limited to these configurations.

The cleaning device 50 may clean the surfaces of the substrates LW and UW plasma-treated by the plasma processing device 40. For example, the cleaning device 50 may coat DI water (DWT) on the surfaces of the substrates LW and UW using a spin coater (refer to (b) of FIG. 2).

The aligning device 60 may perform an operation for arranging the substrates LW and UW to have a particular orientation. For example, the substrates LW and UW may be wafers, and the wafers may have a reference portion (e.g., a notch) for arrangement. The aligning device 60 may sense the reference portion and may arrange the substrates LW and UW (refer to (c) of FIG. 2). The substrates LW and UW may be transferred to the substrate bonding device 100 by the first transfer module 70. In one or more examples, the sensing may be performed by using a camera that images the wafers or a depth sensor that senses the notch.

In one or more examples, the substrates LW and UW transferred to the substrate bonding device 100 may be bonded to each other. The substrates LW and UW bonded together may be referred to as a bonding substrate BW (refer to (d) of FIG. 2). The bonding substrate BW may be transferred to the heat processing device 300 by the second transfer module 250, and a heat treatment (or annealing) process may be performed by the heat processing device 300 (refer to (e) of FIG. 2). The substrate bonding device 100 and the heat processing device 300 will be described later.

The receiving module 30 may provide a space for storing the substrates LW and UW. As an example, the substrates LW and UW may be received in a container C with a particular configuration a front opening unified pod or a front opening universal pod (FOUP), and the containers C may be supported in the receiving module 30. The receiving module 30 may store the lower substrate LW, or may store the upper substrate UW and the lower substrate LW, respectively.

The first transfer module 70 may include a robot arm for transferring the substrates LW and UW. The first transfer module 70 may be arranged near the receiving module 30, the plasma processing device 40, the cleaning device 50, the aligning device 60, and the substrate bonding device 100, and may transfer the substrates LW and UW among them. According to one or more embodiments, the first transfer module 70 may be arranged near one side (or a loading region LR to be described) of the substrate bonding device 100. Hence, the first transfer module 70 may load the lower substrate LW to be described in the substrate bonding device 100. The first transfer module 70 may load the upper substrate UW to be described in the substrate bonding device 100.

The substrate bonding device 100 bonds the upper substrate UW on the lower substrate LW loaded by the first transfer module 70. In the process for manufacturing semiconductor products, the substrates (or wafers) may be bonded to each other to manufacture CMOS image sensors (CIS) or high bandwidth memories (HBM). To achieve this manufacturing, the substrate bonding device 100 may bond the substrates, for example, the lower substrate LW and the upper substrate UW.

The second transfer module 250 may unload a bonded substrate structure from the substrate bonding device 100, and may load the same on the heat processing device 300. Hereinafter, the bonded substrate structure formed in the substrate bonding device 100 may be referred to as a bonding substrate BW. For example, the bonding substrate BW may be a structure in which the upper substrate UW is bonded to the lower substrate BW.

According to one or more embodiments, the second transfer module 250 may include a robot arm for unloading the bonding substrate BW on a second side (or the unloading region UR to be described) of the substrate bonding device 100, and loading the same on the heat processing device 300.

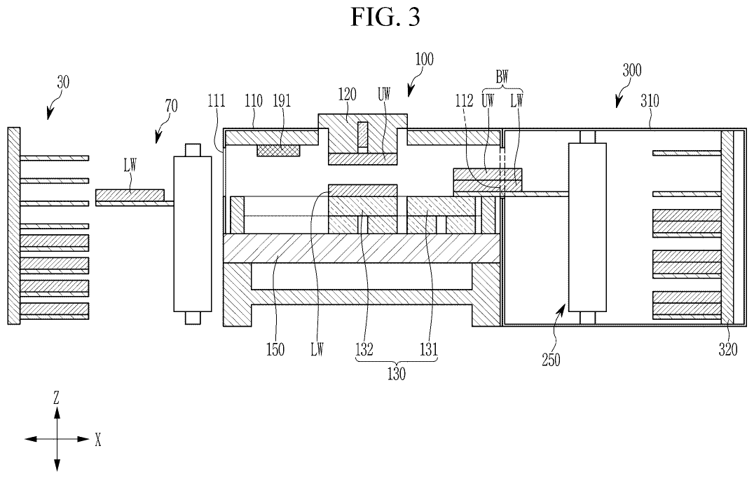

As a first form, the second transfer module 250 may be arranged between the substrate bonding device 100 and the heat processing device 300. As a second form, the second transfer module 250 may be arranged in the heat processing device 300 (refer to FIG. 1 and FIG. 3). In one or more examples, the second transfer module 250 may be the same type of robotic arm as the first transfer module 70.

The heat processing device 300 heat-treats the bonding substrate BW on which the upper substrate UW is bonded to the lower substrate LW. For example, an annealing process for increasing a combination force between the lower substrate LW and the upper substrate UW on the bonding substrate BW may be performed by the heat processing device 300. As understood by one of ordinary skill in the art, an annealing process may be a thermal treatment that improves the crystalline structure of a material, which can lead to lower resistance and better structural quality. The process can also help to understand the growth and nucleation of thin films. The improvement of the crystalline structure may lower electrical resistivity, Annealing may improve surface flatness, thereby making a substrate more suitable for certain applications.

Regarding the bonding substrate BW bonded in the substrate bonding device 100, the upper substrate UW and the lower substrate LW may be bonded by the Van der Waals force, which represents a weak combination force. The upper substrate UW and the lower substrate LW may be bonded together by a covalent bond that is a strong combination force through the annealing process in the heat processing device 300. Accordingly, as understood by one of ordinary skill in the art, the upper substrate UW is bonded to the lower substrate LW without using a medium such as an adhesive.

The heat processing device 300 may include a heater for applying heat at a high temperature. In one or more examples, the heat processing device 300 may include a laser beam irradiator for the purpose of a local heating. However, without being limited thereto, the heat processing device 300 may include various types of heating means for increasing the combination force between the lower substrate LW and the upper substrate UW of the bonding substrate BW.

According to one or more embodiments, the heat processing device 300 may be arranged near the second side (or the unloading region UR) of the substrate bonding device 100. The heat processing device 300 may heat-treat the bonding substrate BW unloaded from the substrate bonding device 100. According to one or more embodiments, the heat processing device 300 may be arranged in-line with the substrate bonding device 100. The heat treatment process in the heat processing device 300 may be performed in continuation of the bonding process in the substrate bonding device 100.

The substrate bonding device 100 and the heat processing device 300 will now be described in detail.

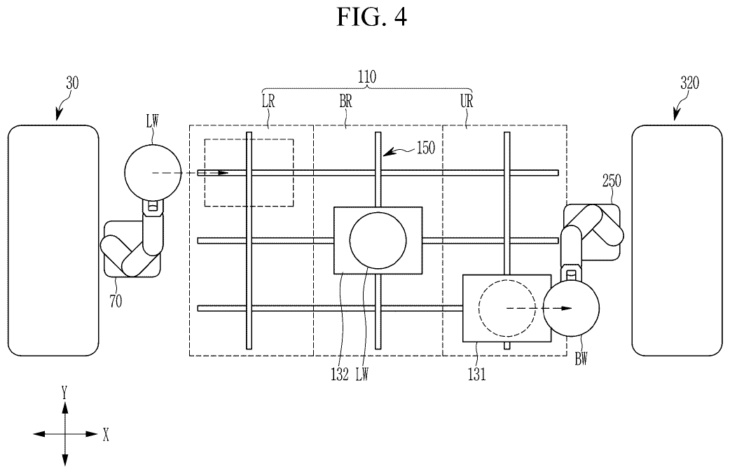

FIG. 3 shows a cross-sectional view of a substrate bonding device according to one or more embodiments, and FIG. 4 shows a top plan view of a substrate bonding device according to one or more embodiments. For ease of description, FIG. 4 shows an inside of the substrate bonding device. FIG. 3 and FIG. 4 also show the heat processing device.

Referring to FIG. 3 and FIG. 4, the heat processing device 300 may include a heat treatment chamber 310 and a heating module 320.

The heat treatment chamber 310 may be arranged near the substrate bonding device 100. For example, the heat treatment chamber 310 may be continuously arranged with the bonding chamber 110.

The heat treatment chamber 310 may have a loading hole for loading the bonding substrate BW. The loading hole may be made as an opening, and may have an additional opening/closing means. The loading hole may be connected to an unloading hole of the bonding chamber 110. Therefore, the process of unloading from the bonding chamber 110 may correspond to loading into the heat treatment chamber 310. The unloading from the bonding chamber 110 and the loading into the heat treatment chamber 310 may be simultaneously or continuously performed.

The heating module 320 may be arranged in the heat treatment chamber 310. The heating module 320 may include a support for supporting the bonding substrate BW and a heating means for heating the bonding substrate BW. For example, the heating module 320 may be partitioned into spaces. The heating module 320 may include a casing closed and sealed from an outside.

According to one or more embodiments, the second transfer module 250 may be arranged in the heat treatment chamber 310. A second transfer module 250 may be arranged between the loading hole of the heat treatment chamber 310 and the heating module 320.

The bonding substrate BW unloaded from the substrate bonding device 100 may be continuously loaded on the heat processing device 300 by the second transfer module 250. Continuous loading and unloading may refer to unloading a processed substrate from a first region to a second region while a another substrate is loaded into the first region. Therefore, a reduction in time and equipment for transferring the bonding substrate BW to the heat processing device when the bonding is completed may be achieved. The bonding and the annealing process may be continuously performed so productivity of the process may be increased. Furthermore, the tilting and de-bonding of the two bonded substrates generated when moving the bonding substrate BW may be prevented.

The substrate bonding device 100 will now be described in detail.

Referring to FIG. 3, the substrate bonding device 100 includes a bonding chamber 110, an upper chuck 120, and lower chucks 130. The substrate bonding device 100 may further include a stage 150 for moving the lower chucks 130.

The bonding chamber 110 may include an internal space for receiving the upper chuck 120 and the lower chucks 130. A vacuum pressure or an atmospheric pressure may be formed in the internal space of the bonding chamber 110. A first opening/closing member 111 for loading the lower substrate LW may be provided on the first side of the bonding chamber 110. A second opening/closing member 112 for unloading the bonding substrate BW may be provided on the second side of the bonding chamber 110. In one or more examples, the first opening and the second opening may be provided on the first side and the second side of the bonding chamber 110, respectively.

Referring to FIG. 4, the bonding chamber 110 may have the loading region LR, the bonding region BR, and the unloading region UR. For example, the internal space of the bonding chamber 110 may be classified into the loading region LR, the bonding region BR, and the unloading region UR.

The loading region LR on which the lower substrate LW is loaded may be arranged on one side of the bonding chamber 110. A first sensing unit 191 may be provided in the loading region LR. The first sensing unit 191 may sense a position of the lower substrate LW supported on the lower chuck 130. For example, the first sensing unit 191 may sense an arranged state between the lower substrate LW and the lower chuck 130. The first sensing unit 191 may include various types of sensors or vision cameras. For example, the first sensing unit 191 may be position sensing circuitry configured to detect a position of a substrate.

The unloading region UR on which the bonding substrate BW is unloaded may be arranged on another side of the bonding chamber 110. The bonding region BR may be arranged between the loading region LR and the unloading region UR, and the upper substrate UW may be bonded on the lower substrate LW in the bonding region BR. According to one or more embodiments, the loading region LR, the bonding region BR, and the unloading region UR may be sequentially arranged in the first direction (X direction).

The upper chuck 120 (FIG. 3) may support the upper substrate UW, and the lower chucks 130 may be moved on the stage 150 to support the lower substrate LW. According to one or more embodiments, the upper substrate UW may be pressurized on the lower substrate LW, and may be bonded thereto in the bonding region BR. The upper chuck 120 and the lower chucks 130 will now be described. As understood by one of ordinary skill in the art, the embodiments are not limited to the configuration in FIG. 4. Although FIG. 4 illustrates that loading region, bonding region, and unloading region being arranged linearly, the embodiments are not limited to this configuration. For example, the loading region, bonding region, and the unloading region may be arranged in a non-linear fashion.

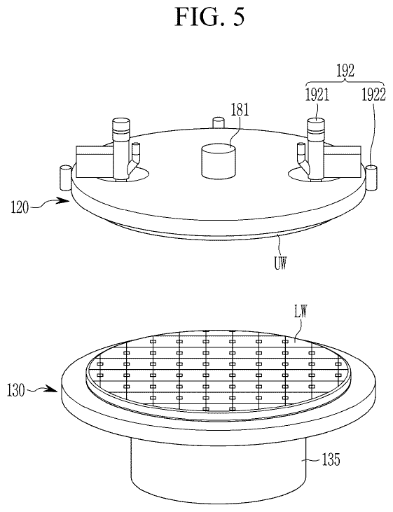

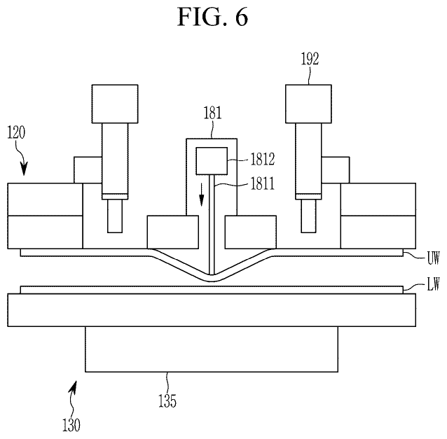

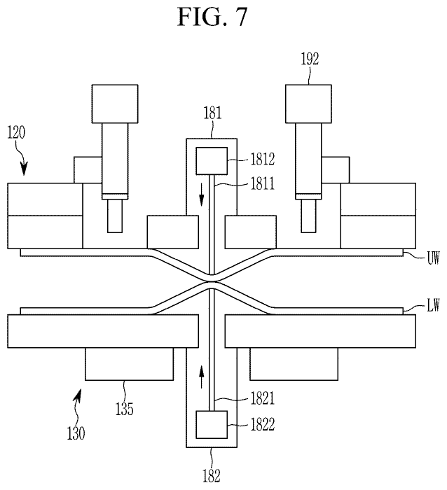

FIG. 5 shows an upper chuck and a lower chuck of a substrate bonding device according to one or more embodiments, and FIG. 6 and FIG. 7 show a process for bonding an upper substrate and a lower substrate by using a substrate bonding device according to one or more embodiments.

The upper chuck 120 may support the upper substrate UW. The upper chuck 120 may be arranged on an upper portion of the internal space of the bonding chamber 110, and may be arranged in the bonding region BR.

A surface of the upper chuck 120 supporting the upper substrate UW may face downward. The upper chuck 120 may support the upper substrate UW in the bonding region BR to face the lower substrate LW supported on the lower chuck 130.

The upper chuck 120 may support the upper substrate UW supplied from the outside of the bonding chamber 110 in the bonding region BR. For example, the upper substrate UW may be loaded into the bonding chamber 110 by the first transfer module 70. The upper substrate UW may be loaded in the bonding region BR. In one or more examples, the upper substrate UW may be loaded in the loading region LR or the unloading region UR. The upper chuck 120 may move to the bonding region BR from the loading region LR, or may move to the bonding region BR from the unloading region UR.

Referring to FIG. 5 and FIG. 6, the upper chuck 120 may include a first pressurizer 181 and a second sensing unit 192.

The first pressurizer 181 may include a first pressurizing member 1811 and a first pressurizing driver 1812. The first pressurizing member 1811 may move upward or downward by the first pressurizing driver 1812. The first pressurizing member 1811 may pressurize the upper substrate UW supported on the upper chuck 120 through the hole provided in a center of the upper chuck 120, downward (toward the lower substrate). The first pressurizing driver 1812 may include a driving source such as a cylinder, a motor, or a solenoid device. In one or more example, the first pressurizing driver 1812 applies a pressure for bonding the upper substrate UW to the lower substrate LW.

It is shown in the drawing that one first pressurizer 181 is provided in the center of the upper chuck 120, which is an example, and the first pressurizers 181 may be provided on many positions of the upper chuck 120.

The second sensing unit 192 may be disposed on the upper chuck 120 and may sense arrangement of the upper substrate UW and the lower substrate LW. For example, the second sensing unit 192 may include two vision cameras, and may obtain an image of the upper substrate UW. The number of the vision cameras is not limited to two, and the second sensing unit 192 may include one or at least three vision cameras. The second sensing unit 192 may include sensors 1922. For example, the sensors 192 may include a distance sensor. The second sensing unit 192 performs the function of aligning the upper substrate UW with the lower substrate LW before the upper substrate UW is bonded to the lower substrate LW (e.g., before pressure is applied).

Referring to FIG. 6, the second sensing unit 192 may sense transformation of the upper substrate UW through the opening installed in the upper chuck 120. For example, the second sensing unit 192 may photograph the image caused by the transformation of the upper substrate UW and may detect a bonding performed position.

In one or more examples, the second sensing unit 192 may sense arrangement of the upper substrate UW on the upper chuck 120.

In one or more examples, the upper chuck 120 may have an adjusting means for finely adjusting the position of the upper substrate UW. Hence, it may adjust the position of the upper substrate UW supported on the upper chuck 120 according to information sensed by the second sensing unit 192. By this, the upper substrate UW may be arranged with respect to the lower substrate LW (refer to (c) of FIG. 2) before the bonding process is performed in the bonding region BR.

The lower chucks 130 supports the lower substrate LW. In one or more examples, the substrate bonding device 100 may have multiple lower chucks 130, thereby maximizing productivity. In one or more example, the lower chucks 130 may have any suitable structure known to one of ordinary skill in the art. Characteristics of the lower chuck 130 may applied in common to the lower chucks 130, and will now be described using the same reference numeral 130.

The lower chuck 130 may support the lower substrate LW. The lower chuck 130 may be arranged on a lower portion of the internal space of the bonding chamber 110. The lower chuck 130 may be horizontally movable in the bonding chamber 110. The lower chuck 130 may move the loading region LR, the bonding region BR, and the unloading region UR.

Referring to FIG. 3 and FIG. 4, a stage 150 may be installed in the bonding chamber 110. The lower chuck 130 may move in a first direction (X direction) and a second direction (Y direction) that is perpendicular to the first direction on the stage 150. Therefore, the lower chuck 130 may move from the loading region LR to the bonding region BR, and subsequently from the bonding region BR to the unloading region UR in the bonding chamber 110.

A surface for supporting the lower substrate LW of the lower chuck 130 may be arranged to face upward. The lower chuck 130 may support the lower substrate LW to face the upper substrate UW supported on the upper chuck 120 in the bonding region BR.

Referring to FIG. 6, the lower chuck 130 may include an arranger 135. The arranger 135 may adjust the position of the lower substrate LW supported on the lower chuck 130. For example, the arranger 135 may horizontally move the lower chuck 130 (movement in the X and Y directions) and may finely tilt (or rotate) the same in the directions (X, Y, and Z directions) of three axes that are perpendicular to each other. By this, the lower substrate LW may be arranged with respect to the upper substrate UW (refer to (c) of FIG. 2) before performing a bonding process in the bonding region BR. In one or more example, the arranger 135 may include one or more motors or actuators that cause a component to move, thereby adjusting a position of a substrate.

The lower chuck 130 may move in the third direction (Z direction) that is perpendicular to the first direction and the second direction through the arranger 135.

In one or more example, referring to FIG. 7, the lower chuck 130 may include a second pressurizer 182. The second pressurizer 182 may include a second pressurizing member 1821 and a second pressurizing driver 1822. The second pressurizing member 1821 may move upward and downward by the second pressurizing driver 1822. The second pressurizing member 1821 may pressurize the lower substrate LW supported on the lower chuck 130 through the hole provided in the center of the lower chuck 130, upward (or toward the upper substrate). The second pressurizing driver 1822 may include the driving source such as a cylinder, a motor, or a solenoid device. Accordingly, the first pressurizer 181 may work in conjunction with the second pressurizer

It is shown in the drawing that one second pressurizer 182 is provided in the center of the lower chuck 130. However, as understood by one of ordinary skill in the art, the embodiments are not limited to this configuration. For example, the lower chuck 130 may include a plurality of second pressurizers 182 provided on many positions of the lower chuck 130.

In one or more examples, the lower chuck 130 may have a sensing means for sensing the arrangement of the lower substrate LW on the upper substrate UW. For example, the lower chuck 130 may include at least one vision camera and may obtain images of the lower substrate LW.

According to one or more embodiments, the lower chucks 130 may be configured to be moveable so that they may be sequentially disposed in the loading region LR, the bonding region BR, and the unloading region UR. Movement of the respective lower chucks 130 may be independently controlled so that one of the lower chucks 130 may be disposed in the bonding region BR and the other may be disposed in at least one of the loading region LR and the unloading region UR. Therefore, while one substrate is bonded, another substrate may be simultaneously moved, loaded, or unloaded, thereby increasing productivity of the process. A configuration for moving the lower chucks 130 according to various embodiments will now be described in detail.

The lower chucks 130 may be configured to be respectively moveable on the stage 150. The lower chucks 130 may include a first lower chuck 131 and a second lower chuck 132. Embodiments in which the lower chucks 130 include two lower chucks will now be described, but are not limited thereto. For example, the lower chucks 130 may include three lower chucks or at least three lower chucks.

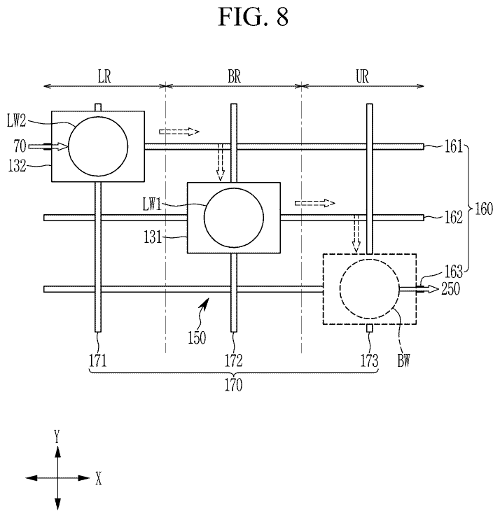

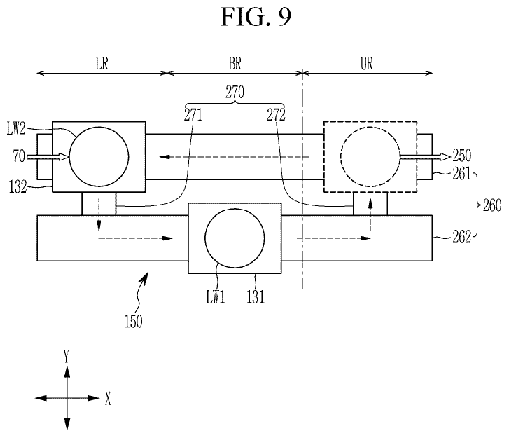

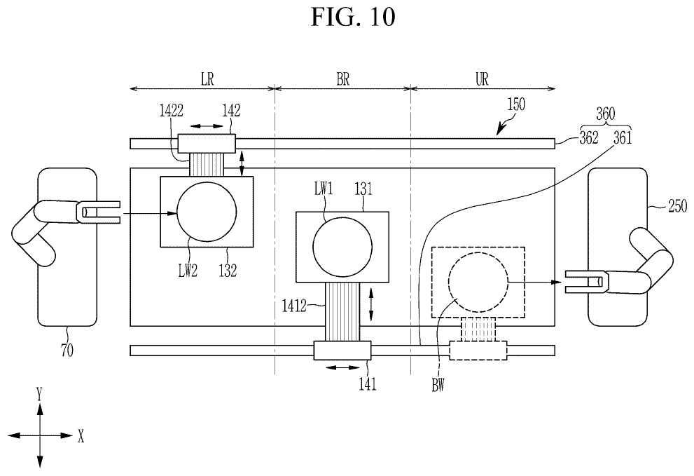

FIG. 8 to FIG. 10 show top plan views of part of a substrate bonding device according to various embodiments. FIG. 8 to FIG. 10 show illustrate an instance in which a bonding process is performed in the substrate bonding device according to various embodiments. For better comprehension and ease of description, the substrate bonding device shown in FIG. 8, FIG. 9, and FIG. 10 will be referred to as a first embodiment, a second embodiment, and a third embodiment. Common parts in the respective embodiments will not be described, and differences will be mainly described.

According to the first embodiment shown in FIG. 8, the stage 150 may include first guide rails 160 and second guide rails 170. The first lower chuck 131 and the second lower chuck 132 may move in first guide rails 160 and second guide rails 170.

In one or more examples, the first guide rails 160 may include three first guide rails 161, 162, and 163 extending to pass through the loading region LR, the bonding region BR, and the unloading region UR, and the second guide rails 170 may cross the first guide rails 160 and may include three second guide rails 171, 172, and 173 for moving the loading region LR, the bonding region BR, and the unloading region UR.

The second guide rails 170 may be connected to the first guide rails 160. The first guide rails 160 may be arranged in parallel to each other in the first direction (X direction), and the second guide rails 170 may be arranged in parallel to each other in the second direction (Y direction). In one or more examples, the second guide rails 170 may be perpendicular to the first guide rails 160 such that first guide rails 160 and the second guide rails 170 form a grid.

According to one or more embodiments, one or more motors or actuators may be provided that cause the lower chucks to move along the first guide rails 160 and the second guide rails 170, thereby enabling for a transition of the lower chuck in the movement direction at intersecting points of the first guide rails 160 and the second guide rails 170. In one or more example, transition between the first and second guide rails or transition of the moving direction of the lower chuck disposed in the intersecting point region may be enabled by any suitable device installed in an intersecting point region of the first guide rails 160 and the second guide rails 170 that causes a lower chuck to switch from moving along the first guide rails 160 to the second guide rails 170. For example, referring to FIG. 8, when the lower chuck 132 transitions from the loading region LR to the bonding region BR, the chuck 132 may be moved along guide rail 161. At the intersection of the guide rails 161 and 172, any suitable device that causes the lower chuck 132 to pivot or rotate from the guide rail 161 to the guide rail 172 may be activated. For example, a bumper or protrusion may be raised that causes the lower chuck 132 moving along the guide rail 161 to pivot or rotate to the guide rail 172.

In the first embodiment, in one or more examples, regarding the movement of the lower chucks 131 and 132, the first lower chuck 131 may be disposed in the loading region LR and may support the first lower substrate LW1 loaded in the loading region LR by a first moving module 70. The first lower chuck 131 supporting the first lower substrate LW1 may move along at least one of the first guide rails 160 and the second guide rails 170 and may be disposed in the bonding region BR. When the first lower chuck 131 is disposed in the bonding region BR, the second lower chuck 132 may be disposed in the loading region LR. The second substrate LW2 loaded in the loading region LR. The first lower chuck 131 disposed in the bonding region BR may bond the upper substrate UW on the supported lower substrate LW1. The first lower chuck 131 supporting the bonding-completed bonding substrate BW may move to the unloading region UR, and the bonding substrate BW may be unloaded by the second moving module 250 in the unloading region UR. When the bonding substrate BW is unloaded, the first lower chuck 131 may move to the loading region LR. When the first lower chuck 131 is disposed in the unloading region UR, the second lower chuck 132 may move to the bonding region BR, and the second lower substrate LW2 may be bonded with the newly loaded upper substrate UW.

In the first embodiment, in one or more examples, the position of the lower chuck loaded with the lower substrate in the loading region LR, the position of the lower chuck undergoing a bonding process in the bonding region BR, and the position of the lower chuck unloading the bonding substrate in the unloading region UR may be disposed at the intersecting point with one of the three first guide rails 161, 162, and 163 (referred to as first-1, first-2, and first-3 guide rails, respectively) and one of the three second guide rails 171, 172, and 173 (referred to as second-1, second-2, and second-3 guide rails).

For example, referring to FIG. 8, the lower chuck on which the lower substrate in the loading region LR is loaded may be disposed on the intersecting point of the first-1 guide rail 161 and the second-1 guide rail 171. The lower chuck undergoing the bonding process in the bonding region BR may be disposed at the intersecting point of the first-2 guide rail 162 and the second-2 guide rail 172. The lower chuck from which the bonding substrate is unloaded in the unloading region UR may be disposed at the intersecting point of the first-3 guide rail 163 and the second-1 guide rail 171.

According to the second embodiment shown in FIG. 9, the stage 150 may include a pair of first guide rails 260 and a pair of second guide rails 270. The first lower chuck 131 and the second lower chuck 132 may move along the one pair of first guide rails 160 and the one pair of second guide rails 170.

In one or more examples, the pair of first guide rails 260 may extend to pass through the loading region LR, the bonding region BR, and the unloading region UR. The pair of second guide rails 270 may connect respective sides facing the one pair of first guide rails 260. For example, the pair of second guide rails 270 may be respectively arranged in the loading region LR and the unloading region UR. In one or more examples, the pair of first guide rails 260 may include guide rails 261 and 262 arranged in parallel to each other in the first direction (X direction), and the pair of second guide rails 270 may include guide rails 271 and 272 arranged in parallel to each other in the second direction (Y direction).

In the second embodiment, regarding the movement of the lower chucks 131 and 132, the first lower chuck 131 may be disposed in the loading region LR and may support the first lower substrate LW1 loaded to the loading region LR by the first moving module 70. The first lower chuck 131 supporting the first lower substrate LW1 may move along at least one of the one pair of first guide rails 260 and the one pair of second guide rails 270 and may be disposed in the bonding region BR. When the first lower chuck 131 is disposed in the bonding region BR, the second lower chuck 132 may be disposed in the loading region LR. The second substrate LW2 loaded in the loading region LR. The first lower chuck 131 disposed in the bonding region BR may bond the upper substrate UW on the lower substrate LW1. The first lower chuck 131 supporting the bonding-completed bonding substrate BW may move to the unloading region UR, and the bonding substrate BW may be unloaded by the second moving module 250 in the unloading region UR. When the bonding substrate BW is unloaded, the first lower chuck 131 may move to the loading region LR. When the first lower chuck 131 is disposed in the unloading region UR, the second lower chuck 132 may move to the bonding region BR and the second lower substrate LW2 supported on the second lower chuck 132 may be bonded with the newly loaded upper substrate UW.

Referring to FIG. 9, in the second embodiment, the position of the lower chuck loaded with the lower substrate in the loading region LR and the position of the lower chuck unloading the bonding substrate from the unloading region UR may be disposed at the intersecting point region of one pair of first guide rails 261 and 262 and one pair of second guide rails 271 and 272. The position of the lower chuck undergoing a bonding process in the bonding region BR may be disposed on one of the first pair of first guide rails 261 and 262.

In the second embodiment, the pair of first guide rails 261 and 262 and the pair of second guide rails 271 and 272 may be arranged to form a closed loop. The lower chucks 130 may sequentially move among the loading region LR, the bonding region BR, and the unloading region UR along the closed loop in a circulating manner. The second embodiment may configure the stage 150 with a simpler structure than that of the first embodiment as a merit.

According to a third embodiment shown in FIG. 10, the stage 150 may include a pair of first guide rails 360, a first support module 141, and a second support module 142. The first lower chuck 131 and the second lower chuck 132 may move along the one pair of first guide rails 360 through the first support module 141 and the second support module 142.

The pair of first guide rails 361 and 362 (referred to as first-1 and first-2 guide rails) may extend in the first direction (X direction), and may be arranged in parallel to each other. The pair of first guide rails 360 may extend to pass through the loading region LR, the bonding region BR, and the unloading region UR. The first-1 guide rail 361 and the first-2 guide rail 362 may be arranged at respective sides of the stage 150 in the second direction (Y direction).

The first-1 guide rail 361 and the first-2 guide rail 362 may be arranged to be spaced from each other in the second direction. The first lower chuck 131 and the second lower chuck 132 may be moved between the first-1 guide rail 361 and the first-2 guide rail 362.

The first support module 141 and the second support module 142 may support the first lower chuck 131 and the second lower chuck 132 to be moveable along one of the pair of first guide rails 360. For example, the first support module 141 may move along the first-1 guide rail 361 and may support the first lower chuck 131. The second support module 142 may move along the first-2 guide rail 362 and may support the second lower chuck 132. The first support module 141 and the second support module 142 may be moved to dispose the first lower chuck 131 and the second lower chuck 132 in the loading region LR, the bonding region BR, and the unloading region UR.

The first support module 141 and the second support module 142 may be connected to the first lower chuck 131 and the second lower chuck 132 so that the first lower chuck 131 and the second lower chuck 132 may move in the second direction (Y direction). According to one or more embodiments, the first support module 141 and the second support module 142 may be connected to the first lower chuck 131 and the second lower chuck 132 to be stretched in the second direction (Y direction).

Referring to FIG. 10, the first support module 141 may include a first connector 1412 stretchable in the second direction and connected to the first lower chuck 131. The second support module 142 may include a second connector 1422 stretchable in the second direction and connected to the second lower chuck 132. In one or more examples, a connector may be stretched by a motor or actuator that causes the connector to move in particular direction. Accordingly, the problem that the first lower chuck 131 moving in the first-1 guide rail 361 and the second lower chuck 131 moving in the first-2 guide rail 362 interfere with each other or collide each other when moving in the first direction may be prevented. A size (a length in the second direction) of the stage 150 may be downsized.

In the third embodiment, regarding the lower chucks 131 and 132, as the first support module 141 moves to the loading region LR, the first lower chuck 131 may be disposed in the loading region LR and may support the first lower substrate LW1 loaded to the loading region LR by the first moving module 70. As the first connector 1412 is stretched, the first lower chuck 131 may be moved in the second direction, and the first lower chuck 131 may be moved to the accurate loading position. As the first support module 141 moves to the bonding region BR along the first-1 guide rail 361, the first lower chuck 131 supporting the first lower substrate LW1 may be disposed in the bonding region BR. When the first lower chuck 131 is disposed in the bonding region BR, as the second support module 142 moves to the loading region LR, the second lower chuck 132 may be disposed in the loading region LR. The second lower chuck 132 disposed in the loading region LR may support the second lower substrate LW2 loaded into the loading region LR. The first lower chuck 131 disposed in the bonding region BR may bond the upper substrate UW on the supported lower substrate LW1. The first support module 141 may move the first lower chuck 131 in the second direction so that the first lower chuck 131 may be accurately disposed at the bonding processed position. For example, the first lower chuck 131 may be moved in the second direction by stretching the first connector 1412. The first support module 141 connected to the first lower chuck 131 supporting the bonding-completed bonding substrate BW may move to the unloading region UR, and in this instance, to accurately dispose the first lower chuck 131 at the unloading position, the first connector 1412 may be stretched to move the first lower chuck 131 in the second direction, and the bonding substrate BW may be unloaded by the second moving module 250 in the unloading region UR. When the bonding substrate BW is unloaded, the first support module 141 connected to the first lower chuck 131 may move to the loading region LR. When the first lower chuck 131 is disposed in the unloading region UR, the second support module 142 connected to the second lower chuck 132 may move to the bonding region BR, and the second lower substrate LW2 supported on the second lower chuck 132 may be bonded with the newly loaded upper substrate UW.

A method for bonding a substrate using the substrate bonding device 100 according to one or more embodiments will now be described.

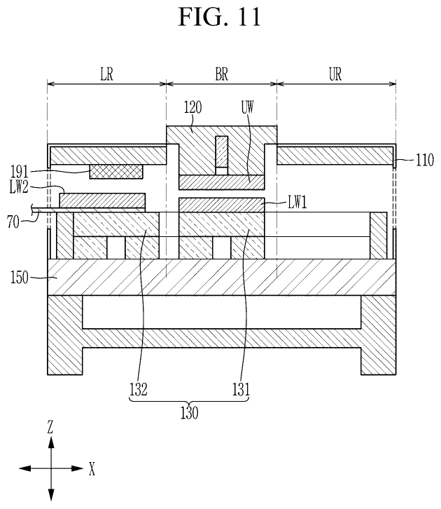

FIG. 11 to FIG. 15 show a method for bonding an upper substrate and a lower substrate using a substrate bonding device according to one or more embodiments.

In one or more examples, the first lower chuck 131 is arranged in the loading region LR to load the first lower substrate LW1 on the first lower chuck 131. The first lower substrate LW1 may be loaded in the loading region LR from the outside of the bonding chamber 110 by the first transfer module 70. In the present stage, arrangement between the first-loaded first lower substrate LW1 and the first lower chuck 131 may be performed through the first sensing unit 191 installed in the loading region LR.

Referring to FIG. 11, the first lower chuck 131 supporting the first lower substrate LW1 is moved to the bonding region BR. The upper chuck 120 may support the upper substrate UW and may be disposed in the bonding region BR. The first lower substrate LW1 and the upper substrate UW may be arranged to face each other. According to one or more embodiments, arrangement between the first lower substrate LW1 and the upper substrate UW may be performed by using the second sensing unit 192.

In the present stage, in detail, the first lower chuck 131 is moved to the bonding region BR, and prior to performing the bonding, the second lower chuck 132 may be arranged in the loading region LR. The second lower substrate LW2 may be loaded on the second lower chuck 132 by arranging the second lower chuck 132 in the loading region LR. The second lower substrate LW2 may be loaded into the loading region LR from the outside of the bonding chamber 110 by the first transfer module 70.

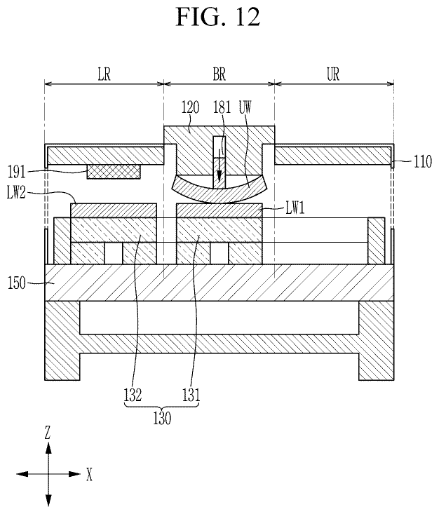

Referring to FIG. 12, the upper substrate UW supported on the upper chuck 120 is bonded to the first lower substrate LW1 supported on the first lower chuck 131 in the bonding region BR. According to one or more embodiments, as the first pressurizer 181 installed in the upper chuck 120 pressurizes the upper substrate UW toward the first lower substrate LW1, the upper substrate UW may be bonded to the first lower substrate LW1. According to another embodiment, the first pressurizer 181 installed in the upper chuck 120 may pressurize the upper substrate UW toward the first lower substrate LW1, and the second pressurizer 182 (refer to FIG. 7) installed in the first lower chuck 131 may pressurize the first lower substrate LW1 toward the upper substrate UW.

In the present stage, the second lower chuck 132 disposed in the loading region LR may not be moved but may maintain its position in a fixed state until the bonding region BR becomes vacant. As a result, vibration generated when the second lower chuck 132 moves may be prevented from giving an influence to the bonding in the bonding region BR.

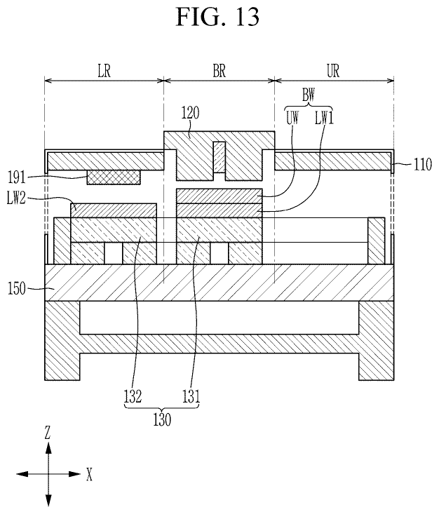

Referring to FIG. 13, the bonding is completed in the bonding region BR. Therefore, the first lower chuck 131 may support the bonding substrate BW on which the upper substrate UW is bonded on the first lower substrate LW1 in the bonding region BR. In this instance, arrangement of the second lower substrate LW2 on the second lower chuck 132 may be sensed in the loading region LR by using the first sensing unit 191. The arrangement of the second lower substrate LW2 on the second lower chuck 132 may be performed by an arranger 135 (refer to FIG. 6 and FIG. 7) installed on the second lower chuck 132.

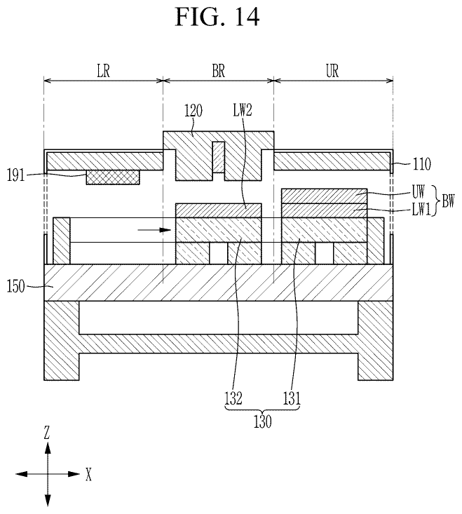

Referring to FIG. 14, the first lower chuck 131 is moved to the unloading region UR. The first lower chuck 131 may move to the unloading region UR from the bonding region BR while supporting the bonding substrate BW. In the present stage, the second lower chuck 132 supporting the second lower substrate LW2 may move to the bonding region BR from the loading region LR.

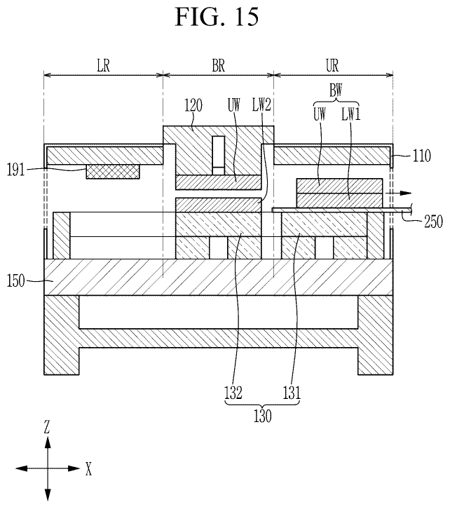

Referring to FIG. 15, the bonding substrate BW is unloaded from the first lower chuck 131 disposed in the unloading region UR. According to one or more embodiments, In the present stage, the second transfer module 250 may load the bonding substrate BW to the heat processing device 300 (refer to FIG. 1 and FIG. 3) when unloading the bonding substrate BW from the unloading region UR.

In the present stage, the upper chuck 120 may load a new upper substrate UW in the bonding region BR to face the second lower substrate LW2 supported on the second lower chuck 132. Accordingly, the upper chuck 120 and the second lower chuck 132 may prepare for a bonding of the upper substrate UW and the second lower substrate LW2.

The first lower chuck 131 may move to the loading region LR from the unloading region UR. A new lower substrate may be loaded on the first lower chuck 131 disposed in the loading region LR, and the upper substrate UW supported on the upper chuck 120 may be bonded on the second lower substrate LW2 supported on the second lower chuck 132 in the bonding region BR.

As described, the lower chucks 130 may move to be sequentially disposed in the loading region LR, the bonding region BR, and the unloading region LR. Further, when one of the lower chucks 130 is disposed in the bonding region BR, the other of the lower chucks 130 may move to be disposed in the loading region LR or the unloading region UR. Hence, productivity of the bonding process may be increased.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A substrate bonding device comprising:
a bonding chamber comprising:
a loading region in which a lower substrate is loaded,
a bonding region in which an upper substrate is bonded to the lower substrate, and
an unloading region spaced from the loading region and unloading the lower substrate to which the upper substrate is bonded in an internal space;
a plurality lower chucks configured to support the lower substrate, each lower chuck moveable to be sequentially disposed in the loading region, the bonding region, and the unloading region; and
an upper chuck configured to support the upper substrate to face the lower substrate in the bonding region.

2. The substrate bonding device of claim 1, wherein movement of a first lower chuck from the plurality of lower chucks is independently controlled from movement of a second lower chuck from the plurality of lower chucks such that the first lower chuck is disposed in the bonding region, and the second lower chuck is disposed in at least one of the loading region and the unloading region.

3. The substrate bonding device of claim 1, wherein:
the loading region, the bonding region, and the unloading region are arranged in a first direction,
a stage configured to support the plurality of lower chucks is installed in the bonding chamber,
the plurality of lower chucks include a first lower chuck and a second lower chuck, and
the first lower chuck and the second lower chuck are moveable in the first direction and a second direction perpendicular to the first direction on the stage.

4. The substrate bonding device of claim 3, wherein:
the stage comprises first guide rails extending in the first direction and second guide rails connected to the first guide rails and extending in the second direction, and
the first lower chuck is moveable in the first guide rails and the second lower chuck is moveable in the second guide rails.

5. The substrate bonding device of claim 3, wherein:
the stage comprises a pair of first guide rails extending in the first direction to pass through the loading region, the bonding region, and the unloading region, and a pair of second guide rails for connecting respective sides, facing each other, of the pair of first guide rails, and
the first lower chuck is moveable in the pair of first guide rails and the second lower chuck is moveable in the pair of second guide rails.

6. The substrate bonding device of claim 3, wherein:
the stage comprises a pair of first guide rails extending in the first direction to pass through the loading region, the bonding region, and the unloading region, a first support module configured to support the first lower chuck to be moveable in one of the pair of the first guide rails, and a second support module configured to support the second lower chuck to be moveable in another of the pair of the first guide rails,
the first support module is connected to the first lower chuck and the second support module is connected the second lower chuck, and
the first support module and the second support module are extendable in the second direction.

7. The substrate bonding device of claim 1, wherein a first sensing circuit configured to sense a position of the lower substrate supported on ta lower chuck from the plurality of lower chucks disposed in the loading region is installed in the loading region.

8. The substrate bonding device of claim 1, wherein the upper chuck comprises:
a first pressurizer configured to pressurize the upper substrate toward the lower substrate supported on the lower chuck in the bonding region, and
a second sensing circuit configured to sense an arrangement between the upper substrate and the lower substrate.

9. The substrate bonding device of claim 1, wherein each of the plurality of lower chucks comprises an arranging portion configured to adjust a position of the lower substrate.

10. The substrate bonding device of claim 1, wherein each of the plurality of lower chucks comprises a second pressurizer configured to pressurize the lower substrate toward the upper substrate.

11. The substrate bonding device of claim 1, wherein:
the unloading region is arranged adjacent to a heat processing device configured to heat-treat the lower substrate bonded to the upper substrate unloaded from the unloading region, and
the unloading region is connected to the heat processing device through a transfer module configured to unload the lower substrate bonded to the upper substrate from the unloading region and load the lower substrate bonded to the upper substrate on the heat processing device.

12. The substrate bonding device of claim 3, wherein the plurality of lower chucks are moveable in a third direction that is perpendicular to the first direction and the second direction.

13. A substrate bonding system comprising:
a substrate bonding device comprising:
a plurality of lower chucks configured to support a lower substrate, each lower chuck moveable in a first direction and a second direction that is perpendicular to the first direction, and
an upper chuck configured to support an upper substrate that faces the lower substrate on the plurality of lower chucks;
a first transfer module configured to load the lower substrate on the substrate bonding device;
a heat processing device arranged near the substrate bonding device, and the heat processing device configured to heat-treat the lower substrate bonded with the upper substrate unloaded from the substrate bonding device; and
a second transfer module configured to unload a lower substrate bonded with the upper substrate from the substrate bonding device and load the lower substrate bonded with the upper substrate on the heat processing device.

14. The substrate bonding system of claim 13, wherein:
the substrate bonding device further comprises a bonding chamber comprising a loading region arranged in the first direction and loaded with the lower substrate, a bonding region in which the upper substrate is bonded to the lower substrate, and an unloading region configured to unload the lower substrate bonded with the upper substrate in an internal space, and
the plurality of lower chucks are moveable to be sequentially disposed in the loading region, the bonding region, and the unloading region.

15. The substrate bonding system of claim 13, wherein the second transfer module comprises a robot arm installed in the heat processing device, the second transfer module configured to unload the lower substrate bonded with the upper substrate and load the lower substrate bonded with the upper substrate on the heat processing device.

16. The substrate bonding system of claim 13, wherein each of the lower chucks of the plurality of lower chucks comprises a pressurizer configured to pressurize the substrate.

17. The substrate bonding system of claim 13, wherein each of the lower chucks of the plurality of lower chucks comprises an arranging portion configured to adjust a position of the lower substrate.

18. A method for bonding an upper substrate on a lower substrate by using a substrate bonding device including an upper chuck for supporting the upper substrate, and a first lower chuck and a second lower chuck supporting the lower substrate, the method comprising:
arranging the first lower chuck in a loading region to load the lower substrate on the first lower chuck;
moving the first lower chuck from the loading region to a bonding region;
bonding, in the bonding region, the upper substrate supported on the upper chuck to the lower substrate supported on the first lower chuck; and
moving the first lower chuck from the bonding region to an unloading region to unload the lower substrate bonded with the upper substrate,
wherein between the moving of the first lower chuck to the bonding region and the bonding, the second lower chuck is arranged in the loading region to load another lower substrate on the second lower chuck.

19. The substrate bonding method of claim 18, wherein the second lower chuck is moved from the loading region to the bonding region after the first lower chuck is moved from the bonding region to the unloading region.

20. The substrate bonding method of claim 18, wherein the lower substrate bonded with the upper substrate is unloaded from the unloading region and is loaded on a heat processing device disposed adjacent to the unloading region.
